(19) United States
(12) Patent Application Publication
(10) Pub. No.: US 2007/0020890 A1
(43) Pub. Date: Jan. 25, 2007

(54) Method and apparatus for semiconductor processing

(75) Inventors: Randhir Thakur, San Jose, CA (US); Michael Splinter, Los Altos Hills, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/234,487

(22) Filed: Sep. 22, 2005

Related U.S. Application Data
(60) Provisional application No. 60/700,523, filed on Jul. 19, 2005.

(51) Int. Cl. H01L 21/20; C23C 16/00

(52) U.S. Cl. 438/478; 118/719

(57) ABSTRACT

A method and apparatus for manufacturing semiconductors, comprising at least two transfer chambers with exterior walls, at least one holding chamber attached to the transfer chamber, at least one load lock chamber attached to the walls of the transfer chambers, and at least five process chambers attached to the walls of the transfer chambers. A method and apparatus of depositing a high dielectric constant film, comprising depositing a base oxide on a substrate in a first process chamber, providing decoupled plasma nitration to a surface of the substrate in at least one second process chamber, annealing the surface of the substrate in a third process chamber, and depositing polycrystalline silicon in at least one forth process chamber, wherein the first, second, third, and fourth process chambers are in fluid communication with a common interior chamber.

### CROSS-REFERENCE TO RELATED APPLICATIONS

This application claims benefit of U.S. Provisional Patent Application Ser. No. 60/700,523 (APPM/010008L), filed Jul. 19, 2005, which is herein incorporated by reference.

### BACKGROUND OF THE INVENTION

1. Field of the Invention

Embodiments of the invention generally relate to an integrated electronic device processing system configured to perform processing sequences with multiple deposition processing modules.

2. Description of the Related Art

Semiconductor devices are formed by processing substrates in a multi-chamber processing system such as an integrated tool. Multiple chambers in communication with each other in a closed environment are desirable because it reduces chemical and particle contamination and avoids additional power consumption that would arise if the substrates are exposed to room air between chambers. The chambers are segregated by rigid walls, windows, slit valves, and other equipment to protect the rest of the processing system and are accessible to each other by slit valves and robots that transport substrates between the chambers. A controlled processing environment includes a mainframe, a pressure control system, a substrate transfer robot, a load lock, and multiple processing chambers. Processing in a controlled environment reduces defects and improves device yield.

FIG. 1 (Prior Art) depicts a schematic diagram of a multiple process chamber platform for semiconductor substrate processing that is commercially available as the CENTURA™ processing tool manufactured by Applied Materials, Inc. of Santa Clara, Calif. FIG. 2 depicts a schematic diagram of another multiple process chamber platform for semiconductor substrate processing that is commercially available as the ENDURA™ processing tool manufactured by Applied Materials, Inc. of Santa Clara, Calif. These tools can be adapted to utilize single, dual, or multiple blade robots to transfer substrates from chamber to chamber. The details of one such staged-vacuum substrate processing system are disclosed in U.S. Pat. No. 5,186,718, entitled “Staged-Vacuum Substrate Processing System and Method,” issued on Feb. 16, 1993, which is incorporated herein by reference. The exact arrangement and combination of chambers may be altered for purposes of performing specific steps of a fabrication process.

The processing tool 100 depicted in FIG. 1 (Prior Art) contains a plurality of process chambers, 114A-D, a transfer chamber 110, service chambers 116A-B, and a pair of load lock chambers 106A-B. To transport substrates among the chambers, the transfer chamber 110 contains a robotic transport mechanism 113. The transport mechanism 113 has a pair of substrate transport blades 113A attached to the distal ends of extendible arms 113B, respectively. The blades 113A are used for carrying individual substrates to and from the process chambers. In operation, one of the substrate transport blades such as blade 113A of the transport mechanism 113 retrieves a substrate W from one of the load lock chambers such as chambers 106A-B and carries substrate W to a first stage of processing, for example, physical vapor deposition (PVD) in chambers 114A-D. If the chamber is occupied, the robot waits until the processing is complete and then removes the processed substrate from the chamber with one blade 113A and inserts a new substrate with second blade (not shown). Once the substrate is processed, it can then be moved to a second stage of processing. For each move, the transport mechanism 113 generally has one blade carrying a substrate and one blade empty to execute a substrate exchange. The transport mechanism 113 waits at each chamber until an exchange can be accomplished.

Once processing is complete within the process chambers, the transport mechanism 113 moves the substrate W from the last process chamber and transports the substrate W to a cassette within the load lock chambers 106A-B. From the load lock chambers 106A-B, the substrate moves into a factory interface 104. The factory interface 104 generally operates to transfer substrates between pod loaders 105A-D in an atmospheric pressure clean environment and the load lock chambers 106A-B. The clean environment in factory interface 104 is generally provided through air filtration processes, such as, HEPA filtration, for example. Factory interface 104 may also include a substrate orienter/aligner (not shown) that is used to properly align the substrates prior to processing. At least one substrate robot, such as robots 108A-B, are positioned in factory interface 104 to transport substrates between various positions/locations within factory interface 104 and to other location in communication therewith. Robots 108A-B may be configured to travel along a track system within enclosure 104 from a first end to a second end of the factory interface 104.

The processing tool 200 depicted in FIG. 2 (Prior Art) contains, for example, four process chambers 232, 234, 236, and 238, an interior transfer chamber 258, a preclean chamber 222, a cooldown chamber 224, a initial transfer chamber 206, substrate-orienter and degas chambers 218 and 216, and a pair of load lock chambers 202 and 204. The initial transfer chamber 206 is centrally located with respect to the load lock chambers 202 and 204, the substrate orienter and degas chambers 216 and 218, the preclean chamber 222, and the cooldown chamber 224. To effectuate substrate transfer amongst these chambers, the initial transfer chamber 206 contains a first robotic transfer mechanism 210, e.g., a single blade robot (SBR). The substrates are typically carried from storage to the processing tool 200 in a cassette (not shown) that is placed within one of the load lock chambers 202 or 204. The SBR 210 transports the substrates, one at a time, from the cassette to any of the four chambers 212, 214, 216, and 218. Typically, a given substrate is first placed in the substrate orienter and one of the degas chambers 216 and 218, then moved to the preclean chamber 212. The cooldown chamber 214 is generally not used until after the substrate is processed within the process chambers 232, 234, 236, and 238. Individual substrates are carried upon a substrate transport blade that is located at distal ends of a pair of extendible arms of the SBR 210. The transport operation is controlled by a microprocessor controller 201.

The interior transfer chamber 258 is surrounded by, and has access to, the four process chambers 232, 234, 236, and 238, as well as the preclean chamber 222 and the cooldown chamber 224. To effectuate transport of a substrate among the chambers, the interior transfer chamber 258 contains a second transport mechanism 230, e.g., a dual blade robot (DBR). The DBR 230 has a pair of substrate transport blades attached to the distal ends of a pair of extendible arms. In operation, one of the substrate transport blades of the DBR 230 retrieves a substrate from the preclean chamber 222 and carries that substrate to a first stage of processing, for example, physical vapor deposition (PVD) in chamber 232. If the chamber is occupied, the DBR 230 waits until the processing is complete and then exchanges substrates, i.e., removes the processed substrate from the chamber with one blade and inserts a new substrate with a second blade. Once the substrate is processed (i.e., PVD of material upon the substrate), the substrate can then be moved to a second stage of processing, and so on. For each move, the DBR 230 generally has one blade carrying a substrate and one blade empty to execute a substrate exchange. The DBR 230 waits at each chamber until an exchange can be accomplished.

Once processing is complete within the process chambers, the transport mechanism 230 moves the substrate from the process chamber and transports the substrate to the cooldown chamber 222. The substrate is then removed from the cooldown chamber using the first robotic transfer mechanism 210 within the initial transfer chamber 206. Lastly, the substrate is placed in the cassette within one of the load lock chambers, 202 or 204, completing the substrate fabrication process within the integrated tool.

The substrate fabrication process effectiveness is measured by two related factors, device yield and the cost of ownership (COO). These factors directly influence the production cost of an electronic device and a device manufacturer's competitiveness. The COO, while influenced by a number of factors, is most greatly affected by the system and chamber throughput or simply the number of substrates per hour processed using a processing sequence. A process sequence is a combination of device fabrication steps that are completed in one or more processing chambers in the integrated tool. If the substrate throughput in a integrated tool is not limited by robot availability, a long device fabrication step will limit the throughput of the processing sequence, increase the COO, and make a potentially desirable processing sequence impractical.

Integrated tools utilize a plurality of single substrate processing chambers adapted to perform semiconductor device fabrication process. Typical system throughput for conventional fabrication processes, such as a PVD chamber or a CVD chamber, provide a typical deposition process between 30 to 60 substrates per hour. A two to four process chamber system with all the typical pre- and post-processing steps has a maximum processing time of about 1 to 2 minutes. The maximum processing step time may vary based on the number of parallel processes or redundant chambers contained in the system.

The primary benefits of smaller semiconductor devices are improving device processing speed and reducing the generation of heat by the device. Process variability tolerance shrinks as the size of semiconductor devices shrinks. To meet these tighter process requirements, the industry has developed new processes, but they often take more time to complete. For example, some ALD processes require chamber processing time of about 10 to about 200 minutes to deposit a high quality layer on the surface of the substrate, leading to a substrate processing sequence throughput on the order of about 0.3 to about 6 substrates per hour. When forced to use slower processes for improved device performance, the fabrication cost increases because of the slower substrate throughput. Although it is possible to add more chambers to the integrated processing tool to meet the desired throughput, it is often impractical to increase the number of process chambers or tools without significantly increasing the size of a integrated processing tool and the staff to run the tools. These are often the most expensive aspects of the substrate fabrication process.

One factor that can affect device performance variability and repeatability is queue time. Queue time is the time a substrate can be exposed to the atmosphere or other contaminants after a first process has been completed on the substrate before a second process must be completed on the substrate to prevent reduced device performance. If the substrate is exposed to the atmosphere or other sources of contaminants for longer than the acceptable queue time the device performance may be reduced because of contamination of the interface between the first and second layers. Therefore, a process sequence including exposing a substrate to the atmosphere or other sources of contamination must control or minimize the time the substrate is exposed to these sources to prevent device performance variability. Also, a useful electronic device fabrication process must deliver uniform and repeatable process results, minimize contamination, and also provide acceptable throughput to be considered for use in a substrate processing sequence.

High dielectric constant materials, such as metal oxides, are one type of thin film being formed over substrates. Problems with current methods of forming metal oxide films over substrates include high surface roughness, high crystallinity, and/or poor nucleation of the formed metal oxide film.

Therefore, there is a need for improved processes and apparatuses for forming high k dielectric materials over substrates. There is also a need for a system, a method and an apparatus that can process a substrate to meet the required device performance goals and increase the system throughput.

### SUMMARY OF THE INVENTION

The present invention generally provides a method and apparatus for integrated processing of substrates in two or more processing tools, each processing tool having at least one transfer chamber with exterior walls, wherein at least one intermediate chamber connects the processing tools, and wherein the integrated processing tool has at least five process chambers attached to the walls of the transfer chambers. The present invention also generally provides a method and integrated processing tool for depositing a high dielectric constant film in at least five processing chambers located on first and second processing tools connected by one or more intermediate chambers.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (Prior Art) is a schematic view of a prior art processing tool.

FIG. 2 (Prior Art) is a schematic view of an alternative prior art processing tool.

FIG. 3 is a schematic view of an embodiment of an integrated processing tool.

FIG. 4 is a schematic view of an embodiment of an alternative embodiment of an integrated processing tool.

FIG. 5 is a flow chart of one embodiment of a substrate processing sequence.

FIG. 6 is a flow chart of an alternative embodiment of a substrate processing sequence.

FIG. 7 is a flow chart of an additional alternative embodiment of a substrate processing sequence.

FIG. 8 is a flow chart of an additional alternative embodiment of a substrate processing sequence.

FIG. 9 is a flow chart of an additional alternative embodiment of a substrate processing sequence.

FIG. 10 is a flow chart of an additional alternative embodiment of a substrate processing sequence.

FIG. 11 is a flow chart of an additional alternative embodiment of a substrate processing sequence.

FIG. 12 is a cross sectional view of an embodiment of a substrate structure.

FIG. 13 is a cross sectional view of an embodiment of an alternative substrate structure.

FIG. 14 is a schematic view of an alternative embodiment of an integrated tool.

FIG. 15 is a schematic view of an additional alternative embodiment of an integrated tool.

### DETAILED DESCRIPTION

The present invention relates to an integrated processing tool configured to perform extended processing sequences by combining two or ore processing tools.

Processing Tools

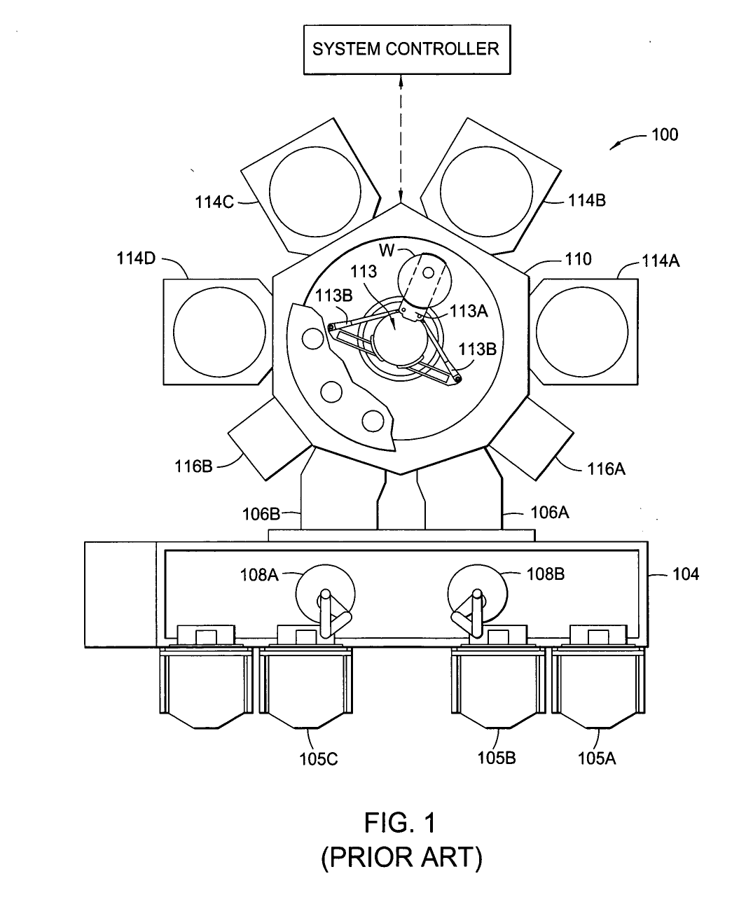

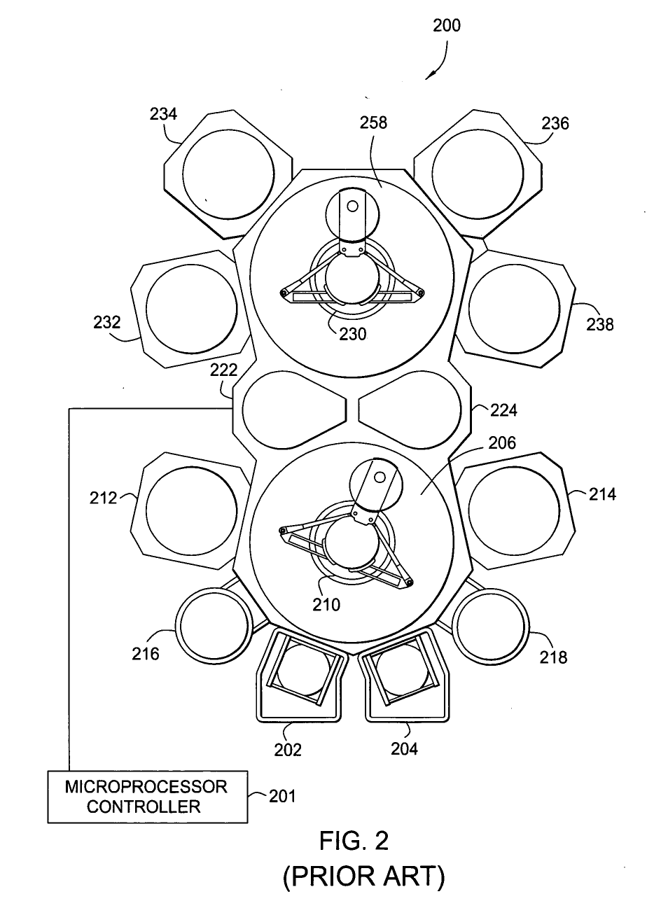

FIGS. 1 and 2 provide embodiments of available processing tools wherein the exact arrangement and combination of processing chambers may be altered for performing specific steps of a fabrication process. However, the total number of processing chambers is limited by several factors including the exterior surface area of the interior chamber for attaching the interchangeable process chambers. That is, interior chamber dimensions have to be selected to balance providing interchangeable process chambers, conserving floor space, and configuring the robots to reach within the interior portions of chambers and the load lock chambers. Also, service chambers may be attached to the exterior surface area of interior chamber.

Integrated Processing Tools with 5 or More Process Chambers

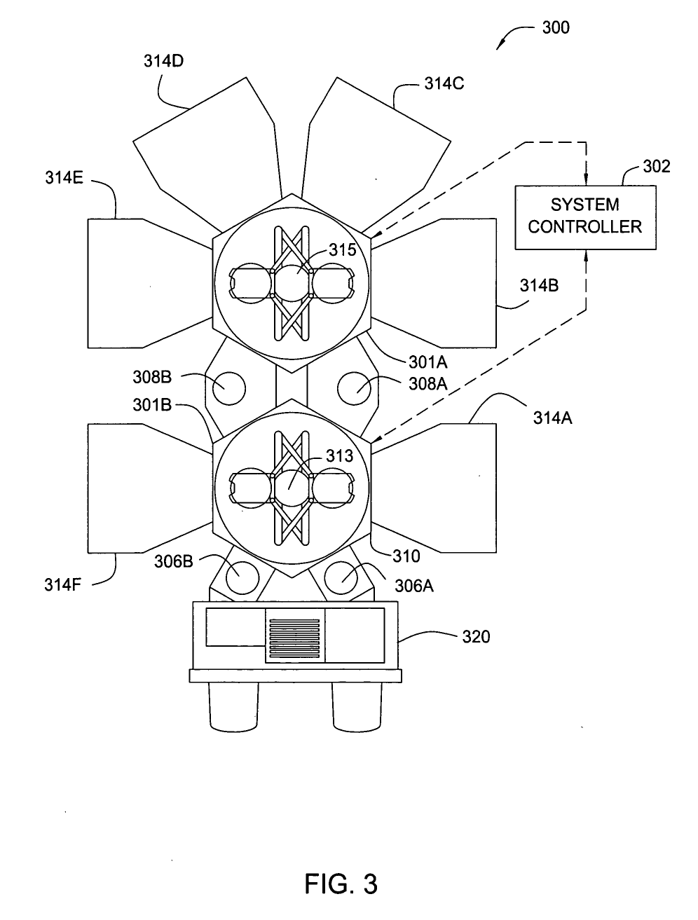

FIG. 3 is a schematic view of an embodiment of an integrated processing tool 300 combining two processing tools 301A, 301B. System controller 302 controls both processing tools 301A, 301B. The interior chamber 310 has two regions 301A, 301B connected by intermediate chambers, 308A, 308B and features additional external surface area for attaching additional process chambers. This shape facilitates placement of service chambers and two load lock chambers 306A-B along the exterior of the region 301B. This shape also provides additional process chambers, up to six process chambers 314A-F. The two regions 301A, 301B of interior chamber 310 are connected by the intermediate chambers 308A, 308B to facilitate communication between robot 315 and robot 313. Intermediate chambers 308A, 308B may be service chambers such as annealing chambers.

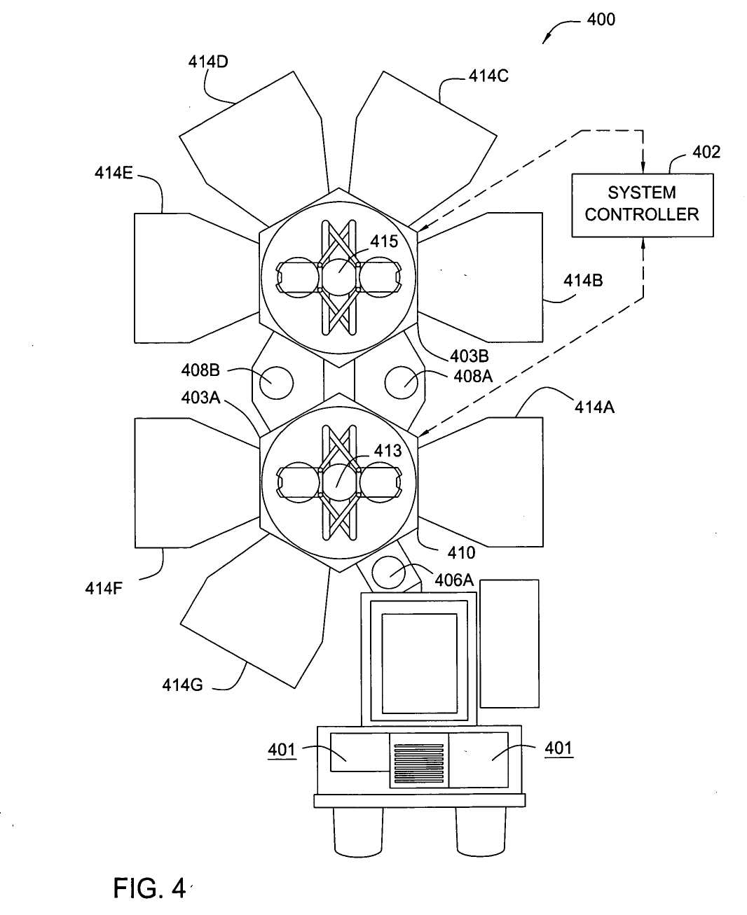

FIG. 4 is a schematic view of an alternative embodiment of an integrated processing tool 400. The length of the tool is increased, but the width of the tool is comparable to smaller systems such as a standard ENDURA™ tool. Thus, the exterior surface area and interior volume of the interior chamber 410 is larger than the standard ENDURA™ tool. The larger exterior surface area allows service chambers and one load lock 406A placed along the exterior surface of the integrated processing tool 400. The substrates are introduced into the processing tool 400 through the front end environment 401. The larger exterior surface area also provides locations for additional process chambers 414A-G, i.e. seven process chambers. The two regions 403A, 403B of interior chamber 410 are connected by intermediate chambers 408A, 408B to facilitate communication between robot 415 and robot 413. Intermediate chambers 408A, 408B may be service chambers. The load lock 406A may be an over and under load lock such as an over and under load lock chamber described in U.S. Pat. No. 5,961,269 which is hereby incorporated by reference herein.

For both of the embodiments of FIG. 3 and 4, the placement of the system controllers 302, 402, service chambers, and process chambers 314A-H, 414A-I may be selected for optimum robot access, heat transfer optimization, or other factors. The number of process chambers may also be adjusted from four to six process chambers for the FIG. 3 embodiment and from four to seven process chambers for FIG. 4. The controller parameters may be adjusted for the larger integrated processing tool embodiments. The flow rates of the purge gas, gas delivery system, and exhaust systems may be modified for the larger interior chamber to account for the larger overall integrated processing tool volume.

Load Lock Chambers

The load locks provide a first vacuum interface between the front-end environment and the next transfer chamber. In the embodiment of FIG. 3, two load locks 306A, 306B are provided to increase throughput by alternatively communicating with the transfer chamber 301B and the front-end environment 320. Thus, while one load lock communicates with the transfer chamber, a second load lock can communicate with the front-end environment. In one embodiment, the load locks are a batch type load lock that can receive two or more substrates from the factory interface, retain the substrates while the chamber is sealed and then evacuated to a low enough vacuum level to transfer of the substrates to the transfer chamber. Preferably the batch load locks can retain from 25 to 50 substrates at one time. In one embodiment, the load locks may be adapted to cool down the substrates after processing in the integrated tool. In one embodiment, the substrates retained in the load lock may be cooled by convection caused by a flowing gas from a gas source inlet (not shown) to a gas exhaust (not shown), which are both mounted in the load lock. In another embodiment, the load lock may be fitted with a load lock cassette including a plurality of heat conductive shelves (not shown) that can be cooled. The shelves can be interleaved between the substrates retained in the cassette so that a gap exists between the shelves and the substrates. In this embodiment the shelves cool the substrates radiantly, thereby providing uniform heating or cooling of the substrates so as to avoid damage or warping of the substrates. In another embodiment, the shelves contact a surface of the substrate to cool the substrate by conducting heat away from its surface.

In one embodiment, the integrated tool is adapted to process substrates at a pressure at or close to atmospheric pressure (e.g., 760 Torr) and thus no load locks are required as an intermediate chamber between the factory interface and the transfer chamber. In this embodiment the factory interface robots will transfer the substrate “W” directly to the robot or the factory interface robots may transfer the substrate “W” to a pass-through chamber (not shown), which takes the place of the load locks, so that the robot and the factory interface robots can exchange substrates. The transfer chamber may be continually purged with an inert gas to minimize the partial pressure of oxygen, water, and/or other contaminants in the transfer chamber, the processing chambers mounted in positions and the service chambers. Inert gases that may be used include, for example, argon, nitrogen, or helium.

Service Chambers

Service chambers 308A, B or 408 A, B are adapted for metrology, degassing, orientation, cool down, and other processes. The metrology chamber may provide film thickness measurement or composition analysis. The substrate may be oriented in the service chamber and/or degassed using IR lamps mounted in the service chamber. In one aspect of the invention a preclean process step may be completed on the substrate in the service chamber to remove any surface contamination. The service chambers may be interchanged with any of the process chambers.

Process Chambers

In one aspect of the invention, one or more of the single substrate processing chambers may be an RTP chamber which can be used to anneal the substrate before or after performing the batch deposition step. An RTP process may be conducted using an RTP chamber and related process hardware commercially available from Applied Materials, Inc. located in Santa Clara, California. In another aspect of the invention, one or more of the single substrate processing chambers may be a CVD chamber. Examples of such CVD process chambers include DXZ™ chambers, Ultima HDP-CVD™ chambers, and PRECISION 5000® chambers, commercially available from Applied Materials, Inc., Santa Clara, Calif. In another aspect of the invention, one or more of the single substrate processing chambers may be a PVD chamber. Examples of such PVD process chambers include Endura™ PVD processing chambers, commercially available from Applied Materials, Inc., Santa Clara, Calif. In another aspect of the invention, one or more of the single substrate processing chambers may be a DPN chamber. Examples of such DPN process chambers include DPN Centura™ chamber, commercially available from Applied Materials, Inc., Santa Clara, Calif. In another aspect of the invention, one or more of the single substrate processing chambers may be a process/substrate metrology chamber. The processes completed in a process/substrate metrology chamber can include, but are not limited to particle measurement techniques, residual gas analysis techniques, XRF techniques, and techniques used to measure film thickness and/or film composition, such as, ellipsometry techniques.

High Dielectric Constant Film Deposition

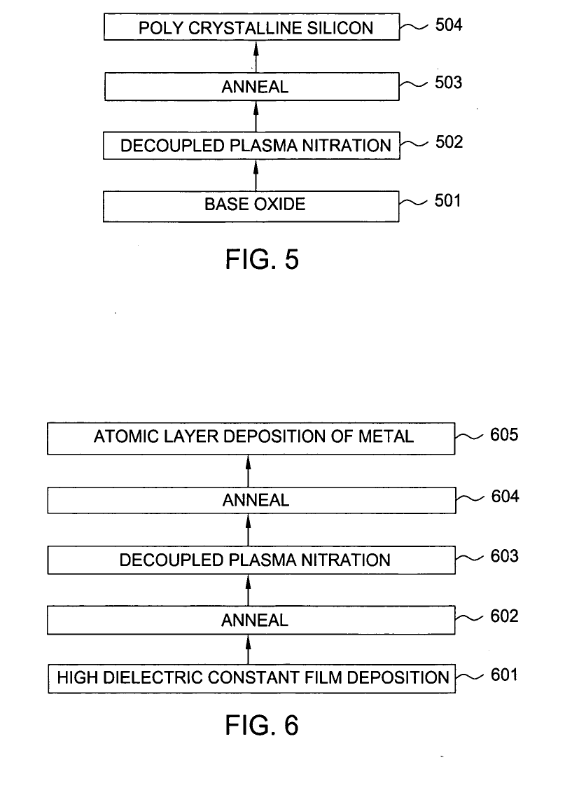

FIGS. 5-11 are process flow diagrams of processes to deposit high dielectric constant (high k) films. Each of these processes requires access to more than three process chambers before relocating the substrate to an additional integrated tool. More chambers are used to split the substrate processing time between chambers. High k film deposition is improved when using multiple process chambers available in one integrated tool with access to the chambers for the multiple process steps. The larger process tool promotes access to process chambers with smaller lag times and reduces exposure to chemicals during transport between tools.

FIG. 5 illustrates depositing a high k film, first depositing a base oxide in step 501. The base oxide may be deposited using in situ steam generation (ISSG) in one process chamber. Next, step 502 treats the deposited oxide with a decoupled plasma nitration. The decoupled plasma nitration may be performed in two process chambers to accelerate the nitration process. Step 503 provides an anneal step. The anneal step may be a rapid thermal anneal and may be performed in one process chamber. Next, step 504 is a polycrystalline silicon deposition step. Step 504 may require two process chambers.

FIG. 6 is an alternative embodiment of a process to deposit high k films. Step 601 is deposition of a high k film using any number of processes such as atomic layer deposition which may be performed in one or two process chambers. Step 602 is an anneal step, which may be a rapid thermal anneal that is performed in one process chamber. Step 603 is a decoupled plasma nitration which is performed in two process chambers. Step 604 is another anneal step performed in one process chamber. Step 605 is an atomic layer deposition step which may be performed in one or two process chambers.

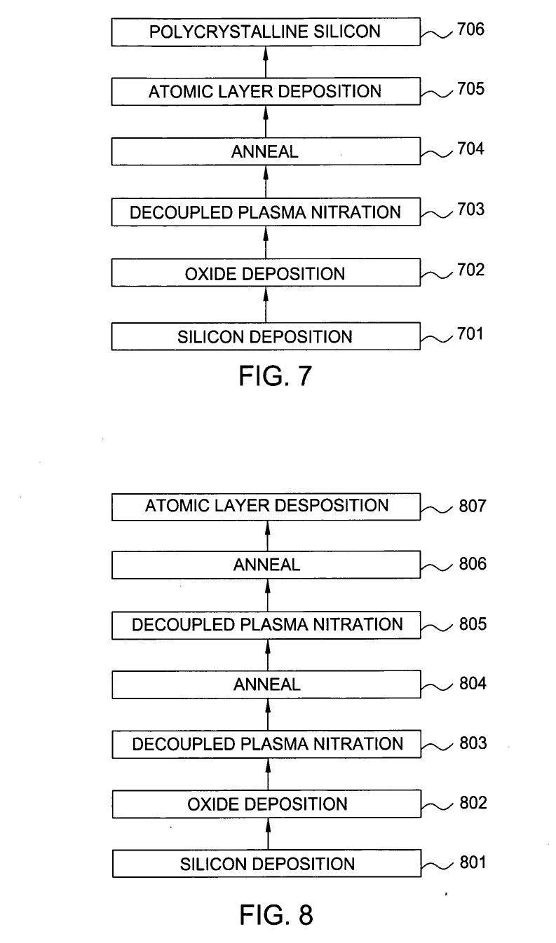

FIG. 7 is an additional embodiment of a process to deposit high k films. Step 701 deposits silicon by, for example, atomic layer deposition using one process chamber. Step 702 deposits oxide using ISSG in one process chamber. Step 703 uses decoupled plasma nitration in two process chambers. Step 704 is an anneal step performed in one process chamber. Step 705 is atomic layer deposition in one or two process chambers. Step 706 is a polycrystalline silicon deposition step which may use two process chambers.

FIG. 8 is an additional alternative embodiment of a process to deposit high k films. Step 801 deposits silicon using atomic layer deposition in one process chamber. Step 802 deposits an oxide using ISSG in one process chamber. Step 803 is a decoupled plasma nitration step using one or two chambers. Step 804 is an anneal step such as rapid thermal anneal in one process chamber. Step 805 is another decoupled plasma nitration step like step 803. Step 806 is an anneal step much like step 804. Step 807 is an atomic layer deposition step that may use one or two process chambers.

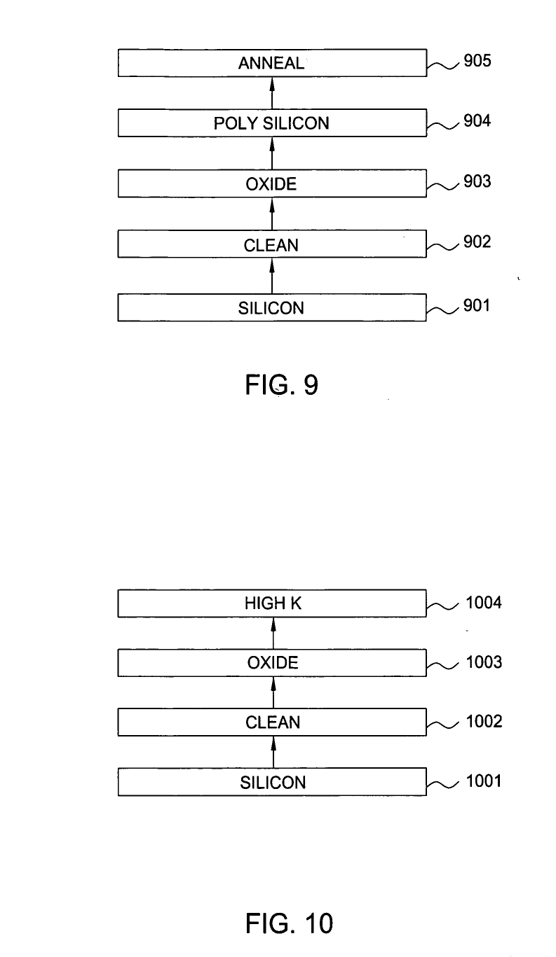

FIG. 9 is an additional embodiment of a process to deposit high dielectric constant films. Step 901 deposits silicon by, for example, atomic layer deposition using one process chamber. Step 902 is a cleaning step to improve the silicon surface. Cleaning may include annealing, plasma cleaning with ozone or other gas, or etching the substrate in one process chamber. Step 903 is an oxide formation step using ISSG or other method in one process chamber. Step 904 is polycrystalline silicon deposition which may use two process chambers. Step 905 anneals using a method such as rapid thermal anneal in one process chamber.

FIG. 10 is an additional embodiment of a process to deposit high dielectric constant films. Step 1001 deposits silicon by, for example, atomic layer deposition using one process chamber. Step 1002 is a cleaning step to improve the silicon surface. Cleaning may include annealing, plasma cleaning with ozone or other gas, or etching the substrate in one process chamber. Step 1003 is an oxide formation step using ISSG or other method in one process chamber. Step 1004 is deposition of a high k film using any number of processes such as atomic layer deposition performed in two process chambers.

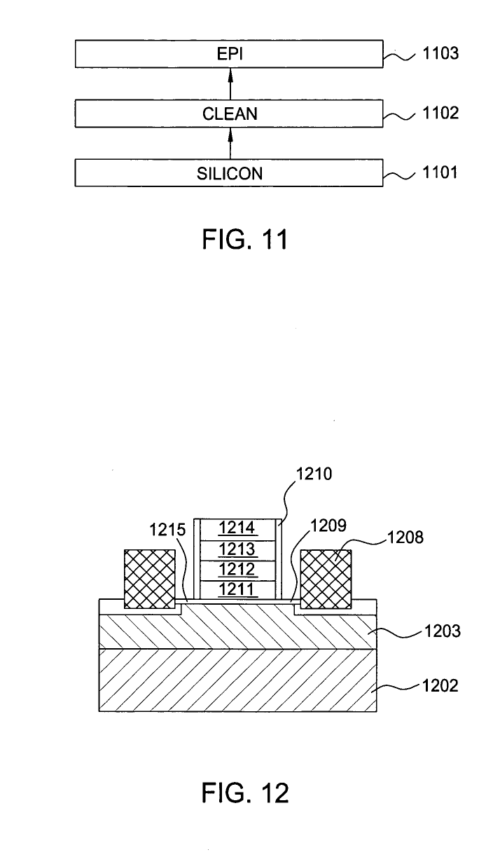

FIG. 11 is an additional embodiment of a process to deposit high dielectric constant films. Step 1101 deposits silicon by, for example, atomic layer deposition using two process chambers. Step 1102 is a cleaning step to improve the silicon surface. Cleaning may include annealing, plasma cleaning with ozone or other gas, or etching the substrate in one process chamber. Step 1103 is an epitaxial deposition step. Silicon, silicon carbide, silicon oxide, or silicon nitride may be deposited epitaxially in two process chambers.

FIG. 12 illustrates a transistor having a gate structure formed according to one embodiment of the invention. The plurality of field isolation regions containing silicon germanium or silicon carbon 1208 isolate a well in the planar layer 1203 of one type conductivity (e.g., p-type) from adjacent wells (not shown) of other type conductivity (e.g., n-type). A gate dielectric layer 1211 is formed on the box oxide 1202 and on well 1203. Typically, gate dielectric layer 1211 may be formed by depositing or growing a layer of a material such as silicon oxide (SiOₙ) and/or silicon oxynitride, having a dielectric constant less than about 5.0. Recent advances in gate dielectric technology indicate that higher dielectric constant materials (K>10) are desirable for forming gate dielectric layer 1211. Examples of suitable materials to be employed therefore include, but are not limited to, metal oxides (Al₂O₃, ZrO₂, HfO₂, TiO₂, Y₂O₃, and La₂O₃), ferroelectrics (lead zirconate titanate (PZT) and barium strontium titanate (BST)), amorphous metal silicates (HfSiₓO_{y} and ZrSiₓO_{y}), amorphous silicate oxides (HfO₂, and ZrO₂), and paralectrics (BaₓSr₁₋ₓTiO₃ and PbZrₓTi₁₋ₓO₃). High k layers containing these materials may be formed by various deposition processes.

Further, an electrically conductive gate electrode layer 1212 is blanket deposited over gate dielectric layer 1211. Generally, the gate electrode layer 1212 may comprise a material such as doped polysilicon, undoped polysilicon, silicon carbide, or silicon-germanium compounds. However, contemplated embodiments may encompass a gate electrode layer 1212 containing a metal, metal alloy, metal oxide, single crystalline silicon, amorphous silicon, silicide, or other material well known in the art for forming gate electrodes.

A hard-mask layer 1213, such as a nitride layer, is deposited via a CVD process over electrically conductive layer 1212. A photolithography process is then carried out including the steps of masking, exposing, and developing a photoresist layer to form a photoresist mask (not shown). The pattern of the photoresist mask is transferred to the hard-mask layer by etching the hard-mask layer to the top of the gate electrode layer 1212, using the photoresist mask to align the etch, thus producing a hard mask layer 1213 over the gate electrode layer 1212. An additional layer 1214 may be formed over hard mask 1213.

The structure is further modified by removing the photoresist mask and etching the gate electrode layer 1212 down to the top of the dielectric layer 1211, using the hard-mask to align the etch, thus creating a conductive structure including the remaining material of gate electrode layer 1212 underneath the hard-mask. This structure results from etching the gate electrode layer 1212, but not the hard-mask or gate dielectric layer 1211. Continuing the processing sequence, gate dielectric layer 1211 is etched to the top of the planar layer 1203. The gate electrode 1212 and the gate dielectric 1211 together define a composite structure, sometimes known as a gate stack, or gate, of an integrated device, such as a transistor.

In further processing of the gate stack, shallow source/drain extensions 1215 are formed by utilizing an implant process. The gate electrode 1212 protects the substrate region beneath the gate dielectric 1211 from being implanted with ions. A rapid thermal process (RTP) anneal may then be performed to drive the tips 1209 partially underneath the gate dielectric 1211.

Next, a conformal thin oxide layer 1210 is deposited over the entire substrate surface. This oxide layer is used to protect the silicon surface from the spacer layer (not shown), which is typically a silicon nitride layer. The conformal thin oxide layer is typically deposited with TEOS source gas in a low pressure chemical vapor deposition chamber at high temperature (>600° C.). The thin oxide layer relaxes the stress between the silicon substrate and the nitride spacer and it also protects the gate corners from the silicon nitride spacer by providing another layer of material. If low k and non-silicon-nitride material is used as sidewall spacer, this conformal thin oxide layer 1210 can possibly be eliminated or replaced by another low k material.

For advanced device manufacturing, if the dielectric constant of the spacer layer (not shown) or oxide layer 1210 is too high, the resulting structure often results in excessive signal crosstalk. In addition, thermal CVD processes used to deposit silicon nitride often require high deposition temperature. The high deposition temperature often results in high thermal cycle and an altered dopant profile of tip 1209. Therefore, it is desirable to have a spacer layer deposition process with lower deposition temperature.

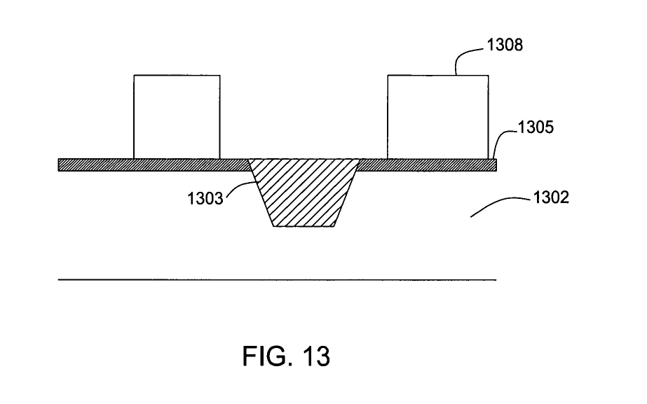

FIG. 13 illustrates a transistor having a gate structure formed according to one embodiment of the invention. The isolation oxide 1303 is formed in the planar layer 1302. An active area 1305 is silicon or silicon containing material that has been cleaned by a process such as an ozone plasma. Field isolation regions 1308 are silicon or silicon containing material such as silicon germanium.

Being able to utilize multiple chambers in one integrated tool provides a way to optimize heat distribution. It also provides opportunities to optimize metal film properties and resulting DRAM and STI formation. High k films are desirable for manufacturing applications that produce high k metal gate stack structures.

Alternative Integrated Processing Tools with 8 or More Process Chambers

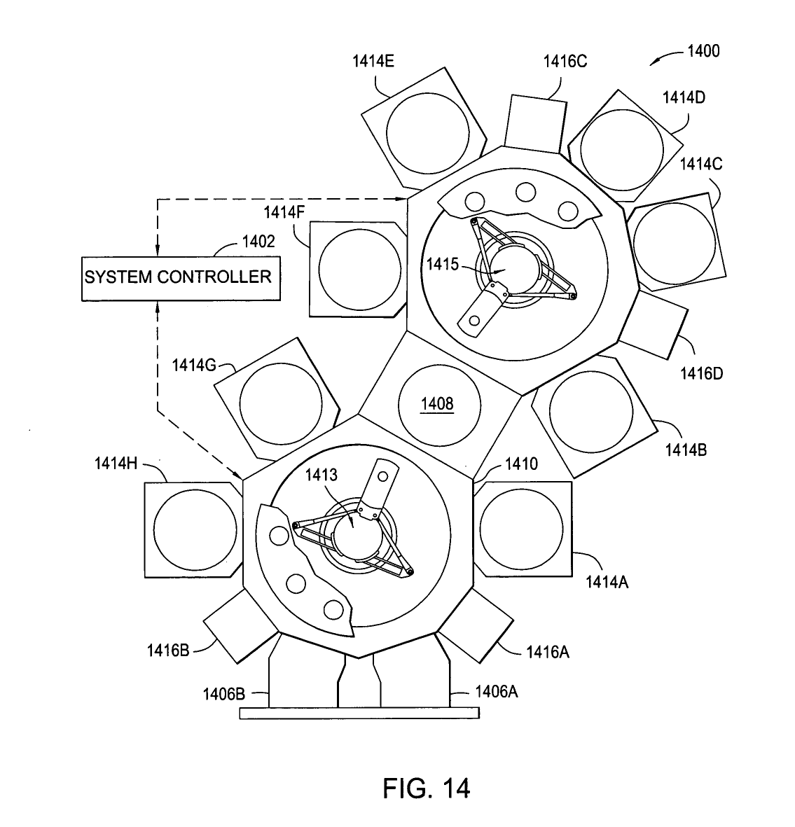

FIG. 14 is a schematic view of an alternative embodiment of an integrated processing tool 1400. System controller 1402 controls the system. The interior chamber 1410 has two regions connected by a holding chamber 1408 and features additional external surface area for attaching additional process chambers. This shape facilitates placement of four service chambers 1416 A-D and two load lock chambers 1406A-B along the exterior of the interior chamber 1410. This shape also provides additional process chambers, up to eight process chambers 1414A-H. The two regions of interior chamber 1410 are connected by the holding chamber 1408 to facilitate communication between robot 1415 and robot 1413. Holding chamber 1408 may be a service chamber.

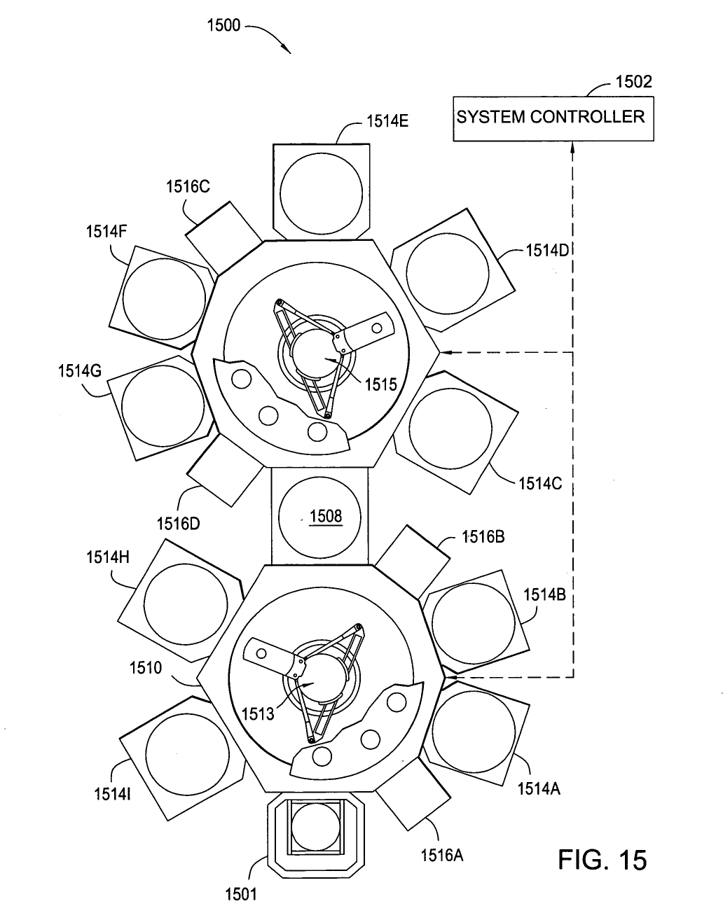

FIG. 15 is a schematic view of an additional alternative embodiment of an integrated processing tool 1500. The length of the tool is increased, but the width of the tool is comparable to smaller systems such as a standard ENDURA™ tool. Thus, the exterior surface area and interior volume of the interior chamber 1510 is larger than the standard ENDURA™ tool. The larger exterior surface area allows four service chambers 1516A-D and one load lock 1501 placed along the exterior surface of the integrated processing tool 1500. The larger exterior surface area also provides locations for additional process chambers 1514A-I, up to nine process chambers. The two regions of interior chamber 1510 are connected by a holding chamber 1508 to facilitate communication between robot 1515 and robot 1513. Holding chamber 1508 may be a service chamber. The load lock 1501 may be an over and under load lock such as an over and under load lock chamber described in U.S. Pat. No. 5,961,269 which is hereby incorporated by reference herein.

For both of the embodiments of FIG. 14 and 15, the placement of the system controllers 1402, 1502, service chambers 1416A-D, 1516A-D, and process chambers 1414A-H, 1514A-I may be selected for optimum robot access, heat transfer optimization, or other factors. The number of process chambers may also be adjusted from four to eight process chambers for the FIG. 14 embodiment and from four to nine process chambers for FIG. 15. The controller parameters may be adjusted for the larger integrated processing tool embodiments. The flow rates of the purge gas, gas delivery system, and exhaust systems may be modified for the larger interior chamber to account for the larger overall integrated processing tool volume.

Alternative Load Lock Chambers

The load locks provide a first vacuum interface between the front-end environment and the next transfer chamber. In the embodiment of FIG. 14, two load locks are provided to increase throughput by alternatively communicating with the transfer chamber and the front-end environment. Thus, while one load lock communicates with the transfer chamber, a second load lock can communicate with the front-end environment. In one embodiment, the load locks are a batch type load lock that can receive two or more substrates from the factory interface, retain the substrates while the chamber is sealed and then evacuated to a low enough vacuum level to transfer of the substrates to the transfer chamber. Preferably the batch load locks can retain from 25 to 50 substrates at one time. In one embodiment, the load locks may be adapted to cool down the substrates after processing in the integrated tool. In one embodiment, the substrates retained in the load lock may be cooled by convection caused by a flowing gas from a gas source inlet (not shown) to a gas exhaust (not shown), which are both mounted in the load lock. In another embodiment, the load lock may be fitted with a load lock cassette including a plurality of heat conductive shelves (not shown) that can be cooled. The shelves can be interleaved between the substrates retained in the cassette so that a gap exists between the shelves and the substrates. In this embodiment the shelves cool the substrates radiantly, thereby providing uniform heating or cooling of the substrates so as to avoid damage or warping of the substrates. In another embodiment, the shelves contact a surface of the substrate to cool the substrate by conducting heat away from its surface.

In one embodiment, the integrated tool is adapted to process substrates at a pressure at or close to atmospheric pressure (e.g., 760 Torr) and thus no load locks are required as an intermediate chamber between the factory interface and the transfer chamber. In this embodiment the factory interface robots will transfer the substrate “W” directly to the robot or the factory interface robots may transfer the substrate “W” to a pass-through chamber (not shown), which takes the place of the load locks, so that the robot and the factory interface robots can exchange substrates. The transfer chamber may be continually purged with an inert gas to minimize the partial pressure of oxygen, water, and/or other contaminants in the transfer chamber, the processing chambers mounted in positions and the service chambers. Inert gases that may be used include, for example, argon, nitrogen, or helium.

Alternative Service Chambers

Service chambers are adapted for degassing, orientation, cool down, and other processes. The substrate may be oriented in the service chamber and/or degassed using IR lamps mounted in the service chamber. In one aspect of the invention a preclean process step may be completed on the substrate in the service chamber to remove any surface contamination.

Alternative Process Chambers

In one aspect of the invention, one or more of the single substrate processing chambers may be an RTP chamber which can be used to anneal the substrate before or after performing the batch deposition step. An RTP process may be conducted using an RTP chamber and related process hardware commercially available from Applied Materials, Inc. located in Santa Clara, Calif. In another aspect of the invention, one or more of the single substrate processing chambers may be a CVD chamber. Examples of such CVD process chambers include DXZ™ chambers, Ultima HDP-CVD™ and PRECISION 5000® chambers, commercially available from Applied Materials, Inc., Santa Clara, Calif. In another aspect of the invention, one or more of the single substrate processing chambers may be a PVD chamber. Examples of such PVD process chambers include Endura™ PVD processing chambers, commercially available from Applied Materials, Inc., Santa Clara, Calif. In another aspect of the invention, one or more of the single substrate processing chambers may be a DPN chamber. Examples of such DPN process chambers include DPN Centura™, commercially available from Applied Materials, Inc., Santa Clara, Calif. In another aspect of the invention, one or more of the single substrate processing chambers may be a process/substrate metrology chamber. The processes completed in a process/substrate metrology chamber can include, but are not limited to particle measurement techniques, residual gas analysis techniques, XRF techniques, and techniques used to measure film thickness and/or film composition, such as, ellipsometry techniques.

While the foregoing is directed to embodiments of the present invention, other and further embodiments of the invention may be devised without departing from the basic scope thereof, and the scope thereof is determined by the claims that follow.

1. An integrated processing tool for manufacturing semiconductors, comprising:
a first processing tool having at least one transfer chamber and at least one load lock attached to the transfer chamber;
a second processing tool having at least one transfer chamber; and
at least one intermediate chamber attached to the first processing tool and the second processing tool;
wherein at least five process chambers are attached to the transfer chambers.

2. The integrated processing tool of claim 1, wherein each transfer chamber is attached to the at least one intermediate chamber by slit valves.

3. The integrated processing tool of claim 1, wherein the first processing tool comprises a single blade robot.

4. The integrated processing tool of claim 3, wherein the second processing tool comprises a dual blade robot.

5. The integrated processing tool of claim 1, wherein the first processing tool has two load lock chambers.

6. The integrated processing tool of claim 1, wherein the at least five process chambers consist of six process chambers.

7. The integrated processing tool of claim 1, wherein the at least five process chambers consist of seven process chambers.

8. The integrated processing tool of claim 1, wherein the at least five process chambers consist of eight process chambers.

9. The integrated processing tool of claim 1, wherein the at least five process chambers consist of nine process chambers.

10. The integrated processing tool of claim 1, further comprising at least one service chamber.

11. The integrated processing tool of claim 10, wherein the at least one service chamber is at least one metrology chamber.

12. An integrated processing tool for manufacturing semiconductors, comprising:
a first transfer chamber configured to support a plurality of process chambers;
a second transfer chamber configured to support a plurality of process chambers;
at least one load lock chamber in communication with the first transfer chamber;
at least one intermediate chamber supported by the first transfer chamber and the second transfer chamber; and
at least five process chambers in communication with the first and second transfer chambers.

13. The integrated processing tool of claim 12, wherein each intermediate chamber is attached to the first and second transfer chambers by slit valves.

14. The integrated processing tool of claim 12, further comprising at least one single blade robot.

15. The integrated processing tool of claim 12, wherein each intermediate chamber is accessible by at least two robots for transport to any of the at least five process chambers.

16. The integrated processing tool of claim 12, having at least two load lock chambers.

17. The integrated processing tool of claim 12, wherein the at least five process chambers are six process chambers.

18. The integrated processing tool of claim 12, wherein the at least five process chambers are seven process chambers.

19. The integrated processing tool of claim 12, wherein the at least five process chambers are eight process chambers.

20. The integrated processing tool of claim 12, wherein the at least five process chambers consist of nine process chambers.

21. The integrated processing tool of claim 12, further comprising at least one service chamber.

22. The integrated tool of claim 21, wherein the at least one service chamber is at least one metrology chamber.

23. A method of depositing a high dielectric constant film, comprising:
depositing a base oxide on a substrate in a first process chamber;
providing decoupled plasma nitration to a surface of the substrate in a second and a third process chamber;
annealing the surface of the substrate in a fourth process chamber; and
depositing polycrystalline silicon in at least one fifth process chamber,
wherein the first, second, third, fourth, and fifth process chambers are in fluid communication with a common intermediate chamber.

24. A method of depositing a high dielectric constant film, comprising:
depositing a base oxide on a substrate in a first process chamber;
providing decoupled plasma nitration to a surface of the substrate in a second and a third process chamber;
annealing the surface of the substrate in a fourth process chamber;
providing decoupled plasma nitration to a surface of the substrate in a fifth and a sixth process chamber;
annealing the surface of the substrate in a seventh process chamber;
providing atomic layer deposition in an eighth process chamber; and
wherein the first, second, third, fourth, fifth, sixth, seventh, and eighth process chambers are in fluid communication with a common intermediate chamber.
